(19) United States
(12) Patent Application Publication
(10) Pub. No.: US 2008/0283915 A1
(43) Pub. Date: Nov. 20, 2008

(54) HIGH VOLTAGE SEMICONDUCTOR DEVICE AND METHOD OF MANUFACTURING THE SAME

(76) Inventor: Duck-Ki Jang, Bucheon-si (KR)

Correspondence Address: SHERR & VAUGHN, PLLC, 620 HERNDON PARKWAY, SUITE 200, HERNDON, VA, 20170, US

(21) Appl. No.: 12/115,639

(22) Filed: May 6, 2008

(30) Foreign Application Priority Data
May 16, 2007 (KR) 10-2007-0047441

(51) Int. Cl. H01L 29/78; H01L 21/336

(52) U.S. Cl. 257/344; 438/296; 257/E21.437; 257/E29.269

(57) ABSTRACT

The present invention provides a high voltage semiconductor device and a method of manufacturing the same. The high voltage semiconductor device includes: a semiconductor substrate; a first high voltage N-type well formed on the semiconductor substrate; a first high voltage P-type well formed inside the first high voltage N-type well; a second high voltage N-type well formed to surround the first high voltage P-type well inside the first high voltage N-type well; a gate dielectric layer and a gate electrode formed to be stacked on the upper of the first high voltage P-type well; and a first N-type high-concentration impurity region formed at both sides of the gate electrode in the first high voltage P-type well, wherein the concentration of the upper region of the first high voltage N-type well is lower than that of the lower region thereof, based on a portion formed with the first high voltage P-type well. Therefore, the present invention can apply bulk bias, simplify a process, improve punch through breakdown voltage in the P-type well formed inside a low-concentration deep N-type well, reduce field of a high-concentration N-type impurity region, and reduce resistance.

The present application claims priority under 35 U.S.C. § 119 to Korean Patent Application No. 10-2007-0047441 (filed on May 16, 2007), which is hereby incorporated by reference in its entirety.

### BACKGROUND

A semiconductor device may use, as a power supply, voltage lower than 3.3V or less to reduce power consumption and to assure its reliability. However, the semiconductor device within one system may be interconnected with other peripheral devices, such peripheral devices using high voltage of more than 5V as a power supply. Therefore, the semiconductor device may include a high voltage transistor for supporting high voltage supplied from the outside.

A high voltage transistor may include a MOS transistor, that is, the same structure as a low voltage transistor and may be simultaneously formed with the low voltage transistor through a series of processes.

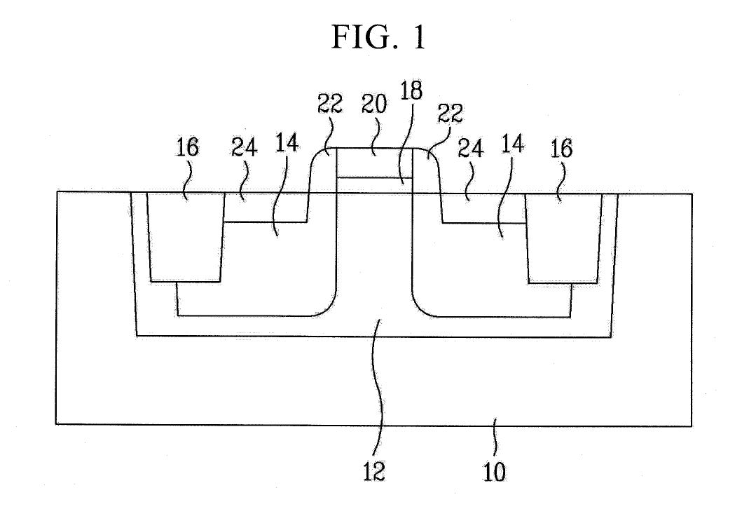

As illustrated in example FIG. 1, a high voltage semiconductor device may include P-type well 12 on and/or over P-type semiconductor substrate 10. Thereafter, masks exposing a device isolation region may be formed on and/or over semiconductor substrate 10. A trench may then be formed by etching substrate regions exposed between the masks. Subsequently, a dielectric layer may be deposited to bury the trench. Thereafter, device isolation layer 16 may be formed by leaving the dielectric layer existing in the trench through a chemical mechanical polishing process.

An oxide film and a polysilicon film may then be stacked on and/or over semiconductor substrate 10, and is patterned to form gate dielectric layer 18 and gate electrode 20 at a predetermined portion on and/or over the upper surface of semiconductor substrate 10. N-type low-concentration impurity ions may then be injected into semiconductor substrate 10 to form N-type low-concentration impurity region 14. A dielectric layer for a spacer such as a nitride film may then be deposited on and/or over semiconductor substrate 10 including gate electrode 20, and is then etched back to form sidewall spacers 22 on sides of gate electrode 20 and gate dielectric layer 18.

High-concentration impurities of the same conductive type as N-type low-concentration impurity region 14 may then be injected into semiconductor substrate 10 in which N-type low-concentration impurity region 14 is formed to form N-type high-concentration impurity region 24. Thereby, a source/drain electrode formed of N-type low-concentration impurity region 14 and N-type high-concentration impurity region 24 may be formed.

In such a semiconductor device, however, a bulk bias cannot be applied to the high-voltage NMOS transistor. Meaning, since well 12 of the high voltage NMOS transistor is a P-type and semiconductor substrate 10 is a P-type, there is a problem that the semiconductor device cannot be designed to apply plus bias to the high voltage NMOS transistor. In this case, the problems that a design of a LCD driver IC (LDI) chip is complicated and a size thereof becomes large occur.

### SUMMARY

Embodiments relate to a high voltage semiconductor device and a method of manufacturing the same that can apply bulk bias by deeply forming an N-type well in a semiconductor device including a high voltage NMOS transistor and then forming an isolated P-type well inside the N-type well, the high voltage NMOS transistor in the P-type well, and forming the N-type well to surround the P-type well.

Embodiments relate to a high voltage semiconductor device and a method of manufacturing the same that can simplify a process by forming an isolated P-type well inside an N-type well and at the same time, forming a P-type well outside an N-type well at the same concentration.

Embodiments relate to a high voltage semiconductor device that can include at least one of the following: a semiconductor substrate; a first high voltage N-type well formed on the semiconductor substrate; a first high voltage P-type well formed inside the first high voltage N-type well; a second high voltage N-type well formed to surround the first high voltage P-type well inside the first high voltage N-type well; a gate dielectric layer and a gate electrode formed to be stacked on the upper of the first high voltage P-type well; and a first N-type high-concentration impurity region formed at both sides of the gate electrode in the first high voltage P-type well, wherein the concentration of the upper region of the first high voltage N-type well being lower than that of the lower region thereof, based on a portion formed with the first high voltage P-type well.

Embodiments relate to a method of manufacturing a high voltage semiconductor device that can include at least one of the following steps: forming a first high voltage N-type well in a semiconductor substrate; forming a second high voltage N-type well to surround edges inside the first high-voltage N-type well; forming a first high-voltage P-type well to be separated from the second high voltage N-type well at a center inside the first high voltage N-type well; forming a device isolation layer between the first high voltage P-type well and the second high voltage N-type well; forming a gate dielectric layer and a gate electrode on the first high voltage P-type well; and forming a first N-type high-concentration impurity region at both sides the gate electrode in the first high voltage P-type well.

### DRAWINGS

Example FIG. 1 illustrates a high voltage semiconductor device.

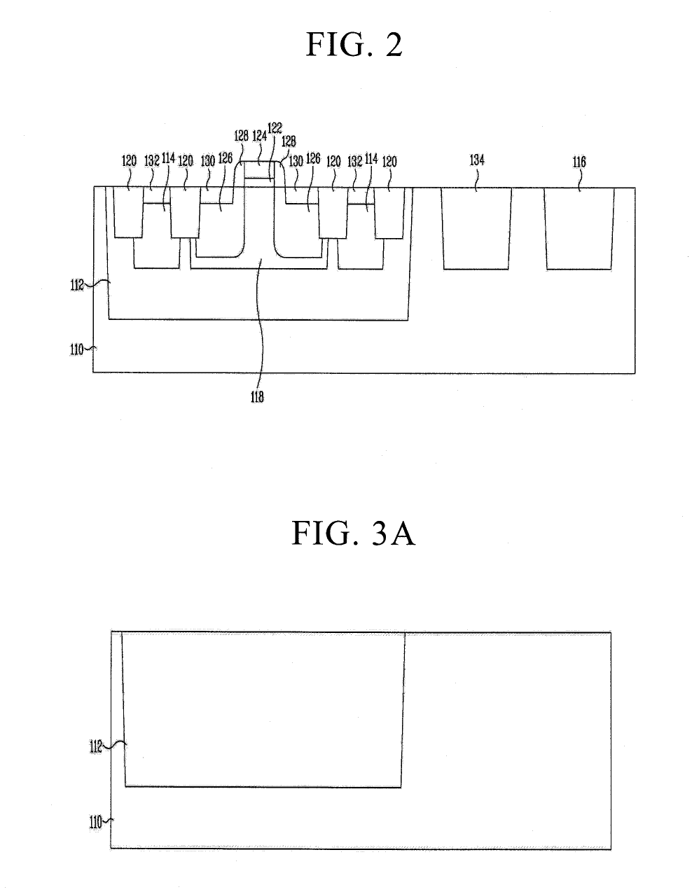

Example FIG. 2 illustrates a high voltage semiconductor device, in accordance with embodiments.

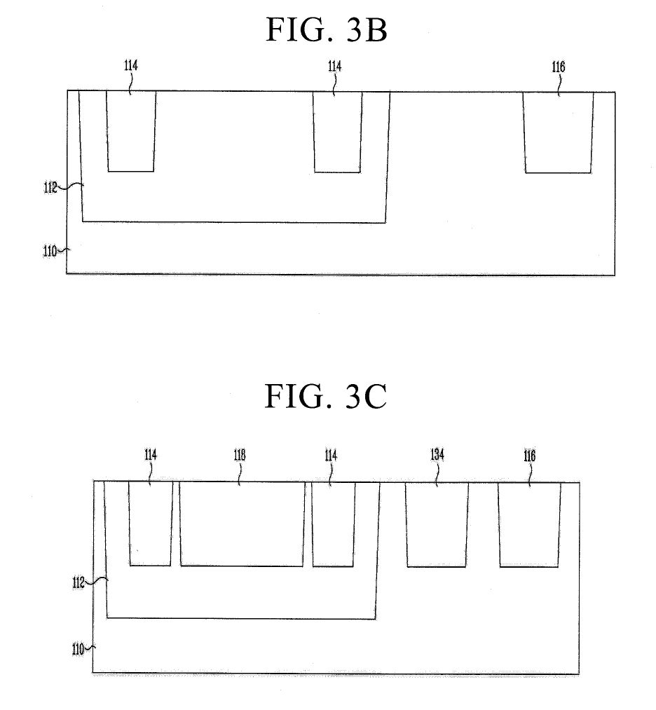

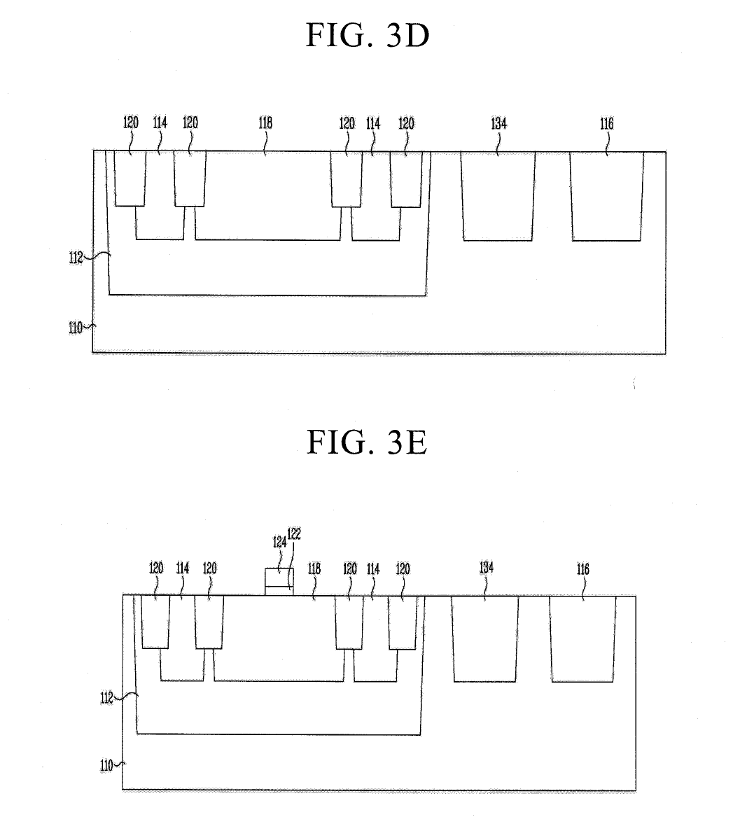

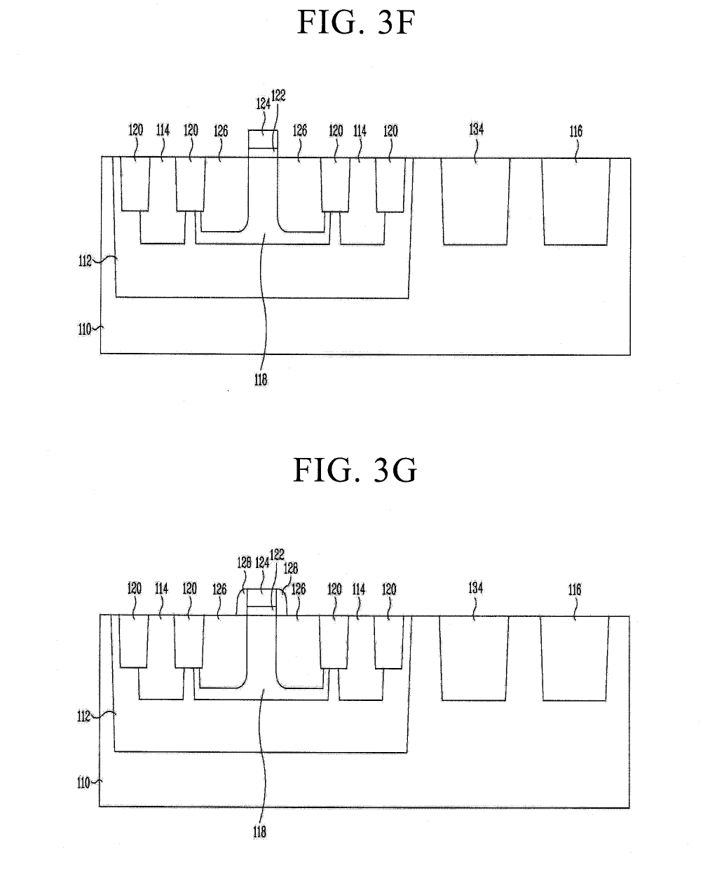

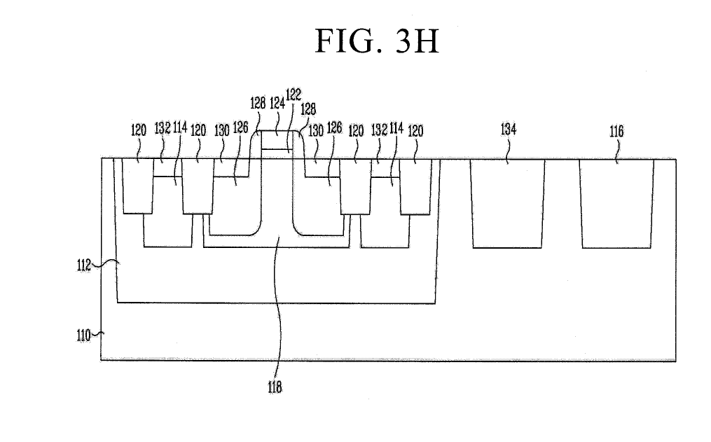

Example FIGS. 3A to 3H illustrate a method of manufacturing a high voltage semiconductor device, in accordance with embodiments.

### DESCRIPTION

As illustrated in example FIG. 2, a high voltage semiconductor device in accordance with embodiments can include semiconductor substrate 110, first high voltage N-type well 112 formed in semiconductor substrate 110, first high voltage P-type well 118 formed inside first high voltage N-type well 112, second high voltage N-type well 114 formed spaced from first high voltage P-type well 118 inside first high voltage N-type well 112, gate dielectric layer 122 and gate electrode 124 formed stacked on and/or over a predetermined portion of the upper surface of first voltage P-type well 118, and source/drain electrodes 126, 130 formed of N-type impurities formed at both sides of gate electrode 124 in first high P-type well 118.

The concentration of the upper region of first high voltage N-type well 112 is different from the concentration of the lower region thereof. The concentration of the upper region is lower than that of the lower region thereof based on a portion, in which first high voltage P-type well 118 is formed inside first high voltage N-type well 112. In other words, the upper region of first high voltage N-type well 112 very lightly doped with N-type impurities.

The high voltage semiconductor device can further include N-type low-concentration impurity region 126 formed under gate electrode 124 within first high voltage P-type well 118, sidewall spacers 128 formed at sides of gate dielectric layer 122 and gate electrode 124, first N-type high-concentration impurity region 130 formed adjacent and under sidewall spacer 128 inside N-type low-concentration impurity region 126, and second N-type high-concentration impurity region 132 formed inside second high voltage N-type well 114.

First high voltage P-type well 118 and second high voltage N-type well 114 are separated from each other by device isolation layer 120. Device isolation layers 120 can also be formed outside second high voltage N-type well 114 to separate it from other external devices.

Second high voltage P-type well 134 and third high voltage N-type well 116 can be formed away from first high voltage N-type well 112. Another device can be formed inside at least one of second high voltage P-type well 134 and third high voltage N-type well 116.

Each one of first high voltage N-type well 112, first high voltage P-type well 118, and second high voltage N-type well 114 can be formed at low concentrations. First high voltage N-type well 112 can be most deeply formed in order that first high voltage P-type well 118 and second high voltage N-type well 114 can be formed therein. First high voltage P-type well 118 can be formed in the center of first high voltage N-type well 112 and second high voltage N-type well 114 can be formed to surround first high voltage P-type well 118 in order to isolate first high voltage P-type well 118 from other devices formed outside first high voltage N-type well 112. Since the concentration of first high voltage N-type well 112 is low so that it cannot completely perform a role of lateral isolation, second high voltage N-type well 114 can be formed at the side of first high voltage P-type well 118 to supplement this and reduce resistance when applying bias.

As illustrated in example FIG. 3A, phosphorous impurity ions can be injected into a predetermined region of semiconductor device 110 using a mask and first high voltage N-type well 112 is formed in semiconductor substrate 110 by performing an annealing process. First high voltage N-type well 112 can be formed at low concentrations and the phosphorous injected at an energy level of 2500 keV or more so that the depth of first high voltage N-type well 112 is deeply formed and the impurities are not diffused to the surface thereof at the same concentration by performing the annealing process from 250 minutes to 300 minutes. In other words, in the concentration of first high voltage N-type well 112, the concentration in the portion for forming first high voltage P-type well 118 is lower than that of the lower region of high voltage P-type well 118. Therefore, the upper region of first high voltage N-type well 112 is lightly doped with N-type impurities.

As illustrated in example FIG. 3B, low-concentration phosphorous impurity ions can be injected in semiconductor substrate 110 using the mask at about 1000 KeV to form a pair of second high voltage N-type wells 114 to eventually surround high voltage P-type well 118 at outer regions of first high voltage N-type well 112. Third high voltage N-type well 116 can also be formed outside first high voltage N-type well 112. Other devices can be formed inside third high voltage N-type well 116, separately from first high voltage N-type well 112. The description of the subsequent processes will be omitted.

As illustrated in example FIG. 3C, boron impurity ions can then be injected in semiconductor substrate 110 using the mask and an annealing process can be performed to form first high voltage P-type well 118 in the center of first high voltage N-type well 118 and second P-type well 134 outside first high voltage N-type well 112. Other devices can be formed inside second high voltage P-type well 134 separately from first high voltage N-type well 112. The description of the subsequent processes will be omitted. First high voltage P-type well 118 and second high voltage P-type well 134 can be formed at the same concentration. Since the upper region of first high voltage N-type well 112, i.e., the portion formed with first high voltage P-type well 118, is lightly doped with N-type impurities, first high voltage P-type well 118 and second high voltage P-type well 134 are formed at the same concentration when boron is injected at the same concentration. Therefore, first high voltage P-type well 118 and second high voltage P-type well 134 can be simultaneously formed inside first high voltage N-type well 112 and outside first high voltage N-type well 112, respectively, using single process and at the same concentration.

As illustrated in example FIG. 3D, after forming a pad nitride oxide on and/or over semiconductor substrate 110 and patterning the pad nitride oxide by a photo and etching process to expose device isolation regions, the exposed regions can be etched to form a plurality of trenches. A dielectric layer can then be deposited to bury the trench. A predetermined thickness of the isolation layer remains on the pad nitride film, and the isolation layer is polished through a chemical mechanical polishing process, thereby forming a plurality of device isolation layers 120. Thereafter, the pad nitride film is etched and removed.

Device isolation layers 120 can be formed between first high voltage P-type well 118 and second high voltage N-type well 114 and also between second high voltage N-type well 114 and other external devices.

As illustrated in example FIG. 3E, an oxide film and a polysilicon film can be sequentially stacked on and/or over semiconductor substrate 110 and then patterned to form gate isolation layer 122 and gate electrode 124 on and/or over a predetermined region of first high voltage P-type well 118.

As illustrated in example FIG. 3F, low-concentration phosphorus impurity ions can then be injected in semiconductor substrate 110 using the mask to form a pair of N-type low-concentration impurity regions 126 on sides of gate electrode 124 in first high voltage P-type well 118. N-type low-concentration impurity regions 126 can be low doped drain (LDD) regions.

As illustrated in example FIG. 3G, a dielectric layer for forming spacers such as a nitride film can then be deposited on and/or over semiconductor substrate 110 including gate electrode 124 and is then etched back to form sidewall spacers 128 on sides of gate electrode 124 and gate dielectric layer 122.

As illustrated in example FIG. 3H, a high-concentration impurity of the same conductive type as N-type low-concentration impurity region 126 can then be injected into semiconductor substrate 110 formed with N-type low-concentration impurity regions 126 to form first N-type high-concentration impurity region 130 in N-type low-concentration impurity regions 126 on sides of side spacers 128 and second N-type high-concentration impurity regions 132 inside second high-voltage N-type well 114. Thereby, the source/drain regions composed of N-type low concentration impurity region 126 and first N-type high impurity region 130 is completed.

In the high voltage semiconductor device in accordance with embodiments, a bias can be applied to the second high voltage N-type well 114 so that the bulk bias can be applied to first high voltage P-type well 118. Second high voltage N-type well 114 can perform a role of isolating first high voltage P-type well 118 from other devices such as second high voltage P-type well 134 and third high voltage N-type well 116.

A semiconductor device such as a liquid crystal display device can have the following advantages. First, in the semiconductor device including the high voltage NMOS transistor, a bulk bias can be applied by deeply forming an N-type well and then forming an isolated P-type well inside the N-type well, forming a high voltage NMOS transistor in the P-type well, and forming an N-type well to surround the P-type well. Second, the process can be simplified by forming the isolated P-type well inside the N-type well and at the same time, forming the P-type well outside the N-type well at the same concentration. Third, the punch through breakdown voltage can be improved in the P-type well formed inside the low-concentration deep N-type well. Lastly, the field of the high-concentration N-type impurity region can be reduced and the resistance can be reduced.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A high voltage semiconductor device comprising:
a semiconductor substrate;
a first high voltage N-type well formed in the semiconductor substrate;
a first high voltage P-type well formed in the first high voltage N-type well;
second high voltage N-type wells formed in the first high voltage N-type well and surrounding the first high voltage P-type well;
a gate dielectric layer and a gate electrode formed stacked on the first high voltage P-type well; and
a first N-type high-concentration impurity region formed at both sides of the gate electrode in the first high voltage P-type well,
wherein the concentration of the upper region of the first high voltage N-type well is lower than that of the lower region thereof based on a portion formed with the first high voltage P-type well.

2. The high voltage semiconductor device of claim 1, further comprising a second N-type high-concentration impurity region formed inside the second high voltage N-type well.

3. The high voltage semiconductor device of claim 1, wherein the first N-type high-concentration impurity regions comprise source and drain electrodes.

4. The high voltage semiconductor device of claim 3, further comprising an N-type low-concentration impurity region formed in the first high voltage P-type well under both sides of the gate electrode.

5. The high voltage semiconductor device of claim 1, further comprising sidewall spacers formed on the sides of the gate dielectric layer and the gate electrode.

6. The high voltage semiconductor device of claim 1, further comprising a second high voltage P-type well formed outside the first high voltage N-type well on the semiconductor substrate.

7. The high voltage semiconductor device of claim 1, further comprising a third high voltage N-type well formed outside the first high voltage N-type well on the semiconductor substrate.

8. The high voltage semiconductor device of claim 1, further comprising a second high voltage P-type well and a third high voltage N-type well formed outside the first high voltage N-type well on the semiconductor substrate.

9. A method of manufacturing a high voltage semiconductor device comprising:
forming a first high voltage N-type well in a semiconductor substrate; and then
forming a pair of second high voltage N-type wells in outer regions of the first high-voltage N-type well; and then
forming a first high-voltage P-type well in a central region of the first high-voltage N-type well and surrounded by the second high voltage N-type wells; and then
forming a device isolation layer between a respective one of the first high voltage P-type well and the second high voltage N-type well; and then
sequentially forming a gate dielectric layer and a gate electrode on the first high voltage P-type well; and then
forming a first N-type high-concentration impurity region at both sides of the gate electrode in the first high voltage P-type well.

10. The method of claim 9, wherein forming the first high voltage N-type well comprises injecting phosphorus impurity ions at an energy level of 2500 keV or more in the semiconductor substrate.

11. The method of claim 10, wherein forming the first high voltage N-type well comprises performing an annealing process from 250 minutes to 300 minutes after the injection of the phosphorus impurity ions.

12. The method of claim 9, further comprising simultaneously forming a second N-type high-concentration impurity region in the second high voltage N-type well during formation of the first N-type high-concentration impurity region.

13. The method of claim 9, wherein the first N-type high-concentration impurity regions comprise source and drain electrodes.

14. The method of claim 7, further comprising, after sequentially forming the gate dielectric layer and the gate electrode, forming an N-type low-concentration impurity region in the first high voltage P-type well on both sides of the gate electrode.

15. The method of claim 14, further comprising, after forming the N-type low-concentration impurity region, forming sidewall spacers on the sides of the gate electrode and the gate dielectric layer.

16. The method of claim 9, further comprising simultaneously forming a third high-voltage N-type well outside the first high voltage N-type well when during formation of the second high voltage N-type well.

17. The method of claim 9, further comprising simultaneously forming a second high voltage P-type well outside the first high voltage N-type well during formation of the first high voltage P-type.

18. A semiconductor device comprising:
a first high voltage N-type well formed in a semiconductor substrate;
a first high voltage P-type well formed in the first high voltage N-type well;
second high voltage N-type wells formed in the first high voltage N-type well on both sides of the first high voltage P-type well;
a gate dielectric layer formed on the first voltage P-type well;
a gate electrode formed on the gate dielectric layer;
first N-type low-concentration impurity regions formed in the first high voltage P-type well under the gate electrode;
first N-type high-concentration impurity regions formed in the first N-type low-concentration impurity regions;
a second N-type high-concentration impurity region formed in the second high voltage N-type wells;
a second high voltage P-type well formed in the semiconductor substrate adjacent the first high voltage N-type well; and
a third high voltage N-type well formed in the semiconductor substrate adjacent the first high voltage N-type well.

19. The semiconductor device of claim 18, wherein the first N-type low-concentration impurity regions and the first N-type high-concentration impurity regions each comprise source/drain electrodes.

20. The semiconductor device of claim 18, further comprising:
a sidewall spacer formed at both sides of the gate dielectric layer and the gate electrode; and
a device isolation layer formed between the first high voltage P-type well and the second high voltage N-type wells.
